(19) United States
(12) Patent Application Publication
(10) Pub. No.: US 2026/0186049 A1
(43) Pub. Date: Jul. 2, 2026

(54) SEMICONDUCTOR TESTING DEVICE AND INSPECTION SYSTEM

(71) Applicant: KABUSHIKI KAISHA NIHON MICRONICS, Tokyo (JP)

(72) Inventors: Hideki IKEUCHI, Musashino-shi (JP); Furawa ODAGIRI, Musashino-shi (JP); Shoujirou YAHATA, Musashino-shi (JP)

(73) Assignee: KABUSHIKI KAISHA NIHON MICRONICS, Tokyo (JP)

(21) Appl. No.: 19/409,670

(22) Filed: Dec. 4, 2025

(30) Foreign Application Priority Data
Dec. 26, 2024 (JP) 2024-230403

(51) Int. Cl. G01R 31/28; G01R 1/073

(52) U.S. Cl. CPC G01R 31/2893; G01R 1/07342

(57) ABSTRACT

A semiconductor testing device includes a main body housing, a plurality of circuit board units inserted and installed inside the main body housing, and an incorrect insertion prevention mechanism having a shape that corresponds to each type of circuit board unit out of the circuit board units, and restricts the circuit board units from being inserted into an incorrect location in the main body housing. The incorrect insertion prevention mechanism includes a pin unit which includes a pin which is disposed in a location that corresponds to the type of the circuit board unit, and a pin receptacle plate having a pin receptacle hole provided in a location where the pin of the pin unit is insertable. The pin unit is installed on a first side of the main body housing and the circuit board unit, while the pin receptacle plate is installed on a second side of the main body housing and the circuit board unit.

The present invention relates to a semiconductor testing device, and an inspection system. Priority is claimed on Japanese Patent Application No. 2024-230403, filed on Dec. 26, 2024, the content of which is incorporated herein by reference.

### BACKGROUND ART

For example, a wafer test system that includes a test head and a prober is disclosed in Patent Document 1 (Japanese Unexamined Patent Application, First Publication No. 2004-172551). The wafer test system disclosed in Patent Document 1 includes the test head, and a test head support/reduction device.

### SUMMARY OF THE INVENTION

A wafer system such as the inspection system disclosed in Patent Document 1 includes a semiconductor testing device, such as the test head of Patent Document 1, which conducts inspection of a semiconductor integrated circuit. The semiconductor testing device includes a housing, and a plurality of circuit board units that are accommodated inside the housing. In other words, a plurality of circuit board units are accommodated inside the housing. Therefore, when assembling the semiconductor testing device, there is a need to prevent having an incorrect circuit board unit from being inserted into an incorrect location.

The present invention is made with the above problem in mind, and an object thereof is to prevent a circuit board unit from being inserted an incorrect location during assembly of a semiconductor testing device that includes a plurality of circuit board units accommodated inside a housing.

The present invention utilizes the following configuration as a means to solve the aforementioned problem.

A semiconductor testing device according to an embodiment of the present invention includes a housing, a plurality of circuit board units inserted and installed inside the housing, and an incorrect insertion prevention mechanism having a shape that corresponds to each type of circuit board unit out of the circuit board units, and restricts the circuit board units from being inserted into an incorrect location in the housing. The incorrect insertion prevention mechanism includes a pin unit which includes a pin which is disposed in a location that corresponds to the type of the circuit board unit, and a pin receptacle having a pin receptacle hole provided in a location where the pin of the pin unit is insertable. The pin unit is installed on a first side of the housing and the circuit board unit, while the pin receptacle is installed on a second side of the housing and the circuit board unit.

An inspection system according to an embodiment of the present invention includes the aforementioned semiconductor testing device, and a test object transport device that transports a test object which has a semiconductor integrated circuit provided thereon, and connects the test object to the semiconductor testing device.

According to the present invention, it is possible to prevent a circuit board unit from being inserted into an incorrect location during assembly of a semiconductor testing device that includes a plurality of circuit board units accommodated inside a housing.

### BRIEF DESCRIPTION OF DRAWINGS

FIG. 1 A schematic diagram showing an outline of an inspection system in an embodiment of the present invention.

FIG. 2 A perspective view of a tester in an embodiment of the present invention.

FIG. 3 An exploded perspective view of the tester in an embodiment of the present invention.

FIG. 4 A front view showing a circuit board unit from a horizontal direction in an embodiment of the present invention.

FIG. 5 An exploded schematic view of a pin unit of a first incorrect insertion prevention mechanism in an embodiment of the present invention.

FIG. 6 An exploded schematic view of a pin unit of a second incorrect insertion prevention mechanism in an embodiment of the present invention

FIG. 7 A schematic exploded view showing a pin receptacle plate of the first incorrect insertion prevention mechanism in an embodiment of the present invention.

FIG. 8 A schematic exploded view of the pin receptacle plate of the second incorrect insertion prevention mechanism in an embodiment of the present invention.

FIG. 9 A schematic plan view of a main body housing when seen from above in an embodiment of the present invention.

### DESCRIPTION OF EMBODIMENTS

Hereinafter, an embodiment of a semiconductor testing device and an inspection system according to the present invention is described with reference to the drawings.

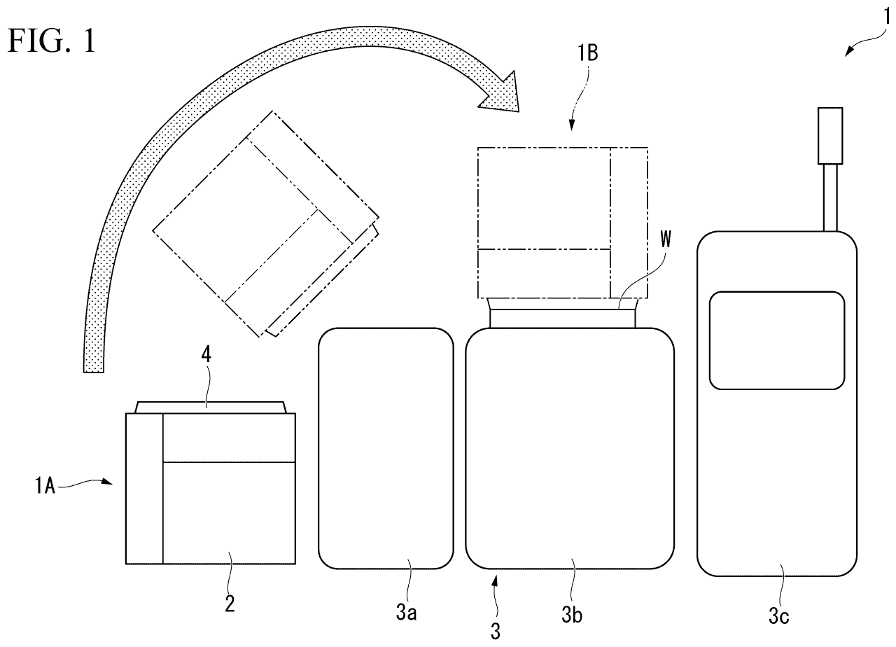

FIG. 1 is a schematic diagram showing an outline of an inspection system 1. The inspection system 1 of the present embodiment conducts inspection of electrical characteristics of a semiconductor integrated circuit, where a wafer W having a semiconductor circuit is provided as a test object. As shown in FIG. 1, the inspection system 1 includes a tester 2 (semiconductor testing device), and a prober 3 (test object transport device). The aforementioned inspection system 1 inspects electrical characteristics of each semiconductor circuit before a plurality of semiconductor circuits which are formed on the wafer W are individually diced into chips.

A probe card 4 is installed in the tester 2. The probe card 4 includes a plurality of probes. The prober 3 causes the probe card 4, having the plurality of probes provided thereon, to contact pads of the plurality of the semiconductor circuits that are formed on the wafer W. The prober 3 includes a tester transport device 3a, a stage device 3b, and a wafer transport device 3c.

The tester transport device 3a includes a transport mechanism that is not shown on the drawings, and moves the tester 2 from the standby location 1A to the inspection location 1B. The stage device 3b supports the wafer W, and aligns a location of the tester 2 and the wafer W located at the inspection location 1B. The stage device 3b is movable in a planar direction along a horizontal plane, and in a vertical direction that is perpendicular to the horizontal plane. The stage device 3b is rotatable around the vertical axis in the θ-direction. The wafer transport device 3c transports the wafer W on the stage device 3b.

When conducting inspection, the stage device 3b moves the wafer W, and causes the pads of the plurality of semiconductors, which are formed on the wafer W to contact tips of the plurality of probes of the probe card 4 provided in the tester 2 which is located in the inspection location 1B. In such state, the tester 2 inputs a test signal simultaneously to each semiconductor circuit via each of the plurality of probes, and by receiving the input signal from each semiconductor circuit, inspects of each semiconductor circuits.

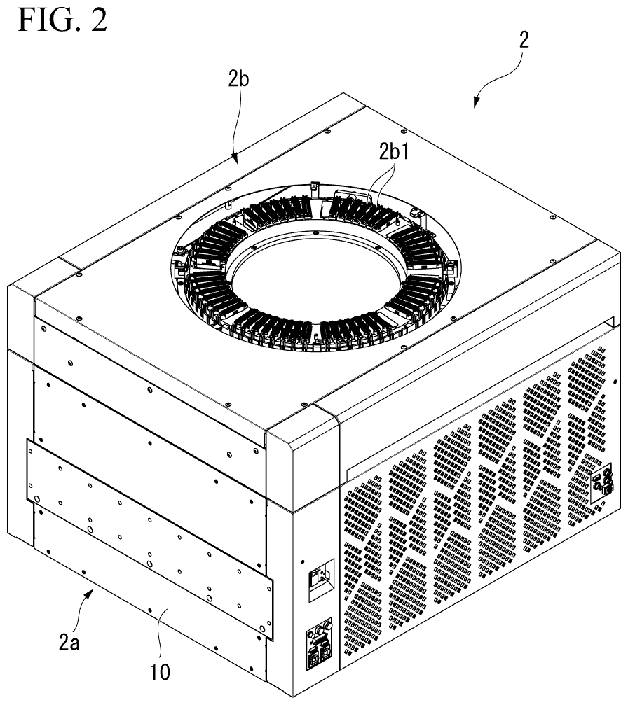

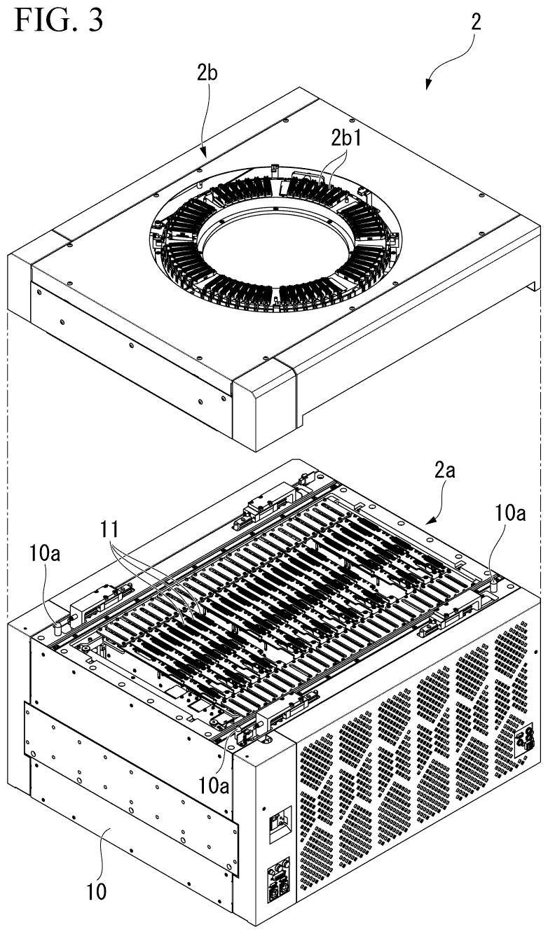

FIG. 2 is a perspective view of a tester 2. Both FIG. 2 and FIG. 3 are exploded views. As can be seen from such drawings, the tester 2 includes a main body 2a and a performance board unit 2b. Both FIG. 2 and FIG. 3 show the tester 2 in a standby position 1A. The tester 2 in the standby position 1A is oriented so as to face above on the side the probe card 4 is installed on. In the explanations hereinafter, explanations are carried out based on a direction where the tester 2 is in a state of being disposed in the standby position 1A.

The main body 2a is a signal processing unit for testing the wafer W, and is detachably supports the performance board unit 2b. The main body 2a includes a main body housing 10 (housing), and a plurality of circuit board units 11. Other than the aforementioned, the main body 2a includes a control processing unit not shown on the drawings. The control processing unit for example, sends control signals to each control board units 11. The control processing unit may also process signals input from each circuit board units 11. A battery may also be accommodated within the main body housing 10, and the control processing unit may include a power unit to distribute power from the battery to each circuit board units 11 or the like.

The main body unit 10 is a housing that accommodates the circuit boards 11. In the present embodiment, the main body housing 10 is a rectangular box that opens from above. A plurality of slots into which the circuit board units 11 are insertable are provided inside the main body housing 10. Each circuit board unit 11 is inserted into each slot, and are accommodated inside the main body housing 10. A plurality of location pins 10a for a performance board unit are provided on an upper surface of the main body housing 10. In a case where the performance board unit 2b is mounted onto the main body 2a from above, the location pins 10a of the performance board unit conduct positioning of the performance board unit 2b in the horizontal direction.

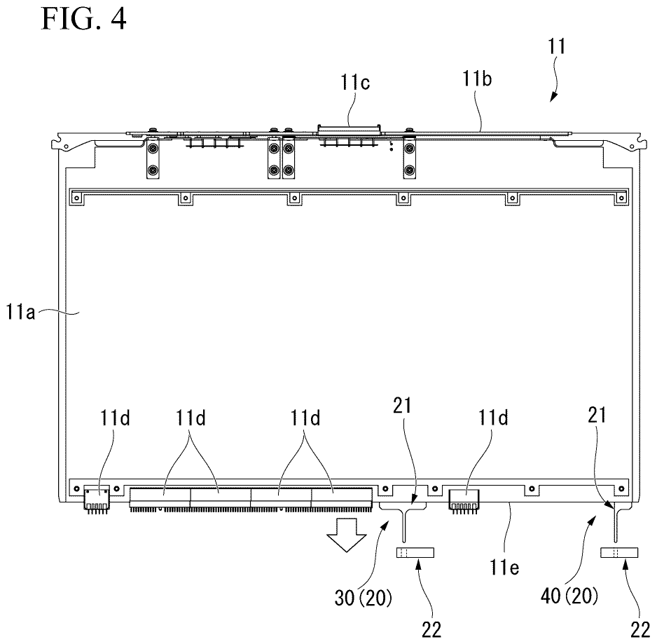

The circuit board unit 11 is a circuit board having electronic components which conduct signal processing of various signals mounted thereon, and is exchangeable depending on the various tests conducted on the wafer W. FIG. 4 is a front view showing the circuit board unit 11 from a horizontal direction. An incorrect insertion prevention mechanism 20 to be mentioned later on is shown on FIG. 4. As shown in FIG. 4, the circuit board unit 11 includes a circuit board main body 11a, an upper plate 11b, an upper connector 11c, and a lower connector 11d.

The circuit board main body 11a is an electronic circuit board, and is accommodated in the main body housing 10 so that a front surface and a rear surface thereof face the horizontal direction. As shown in FIG. 3, the plurality of circuit board units 11 are arranged so as to have the front and rear surfaces of each circuit board main body 11a thereof face one another. In the explanations below, a direction in which the circuit board units 11 are arranged is referred to as a “circuit board arrangement direction” (first direction). In a case where the tester 2 is in a standby position 1A, the circuit board arrangement direction is the horizontal direction. In other words, the circuit board unit 11 includes the circuit board main body 11a which is inserted into the main body housing 10 in an orientation where the front and rear surfaces thereof face the circuit board arrangement direction along the horizontal direction. In the explanations below, a horizontal direction that is orthogonal to the circuit board arrangement direction is referred to as a “circuit board extension direction”.

The upper plate 11b is a band plate member connected to a top end of each of the circuit board main bodies 11a. The upper plate 11b extends along the circuit board extension direction in the planar view. The upper connector 11c is fixed to each of the upper plates 11b. The upper plate 11b may be formed of a single band plate member, and may be formed of a plurality of band plate members.

The upper connector 11c is provided on each of the circuit board main bodies 11a. For example, one to three upper connectors 11c are provided for each circuit board main body 11a. The upper connector 11c is fixed to the upper plate 11b, and is electrically connected to the circuit board main body 11a. The aforementioned upper connector 11c is connectable to a lower connector for a performance board unit, to be mentioned later on, of the performance board unit 2b. By having the upper connector 11c be connected to the lower connector for the performance board unit, the circuit board unit 11 is electrically connected to the performance board unit 2b.

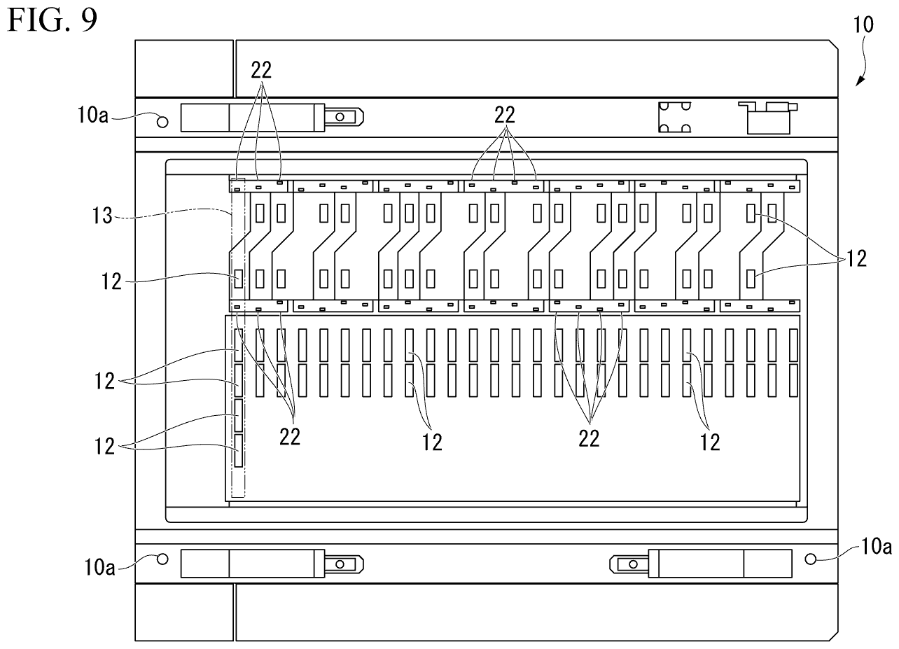

The lower connector 11d is provided on each lower end of the circuit board main body 11a (a lower end edge 11e of the circuit board unit 11). A plurality of bottom connectors 12 (refer to FIG. 9) are provided inside the main body housing 10, on a bottom thereof. Each lower connector 11d is connected to the bottom connector 12. For example, by having the circuit board unit 11 connected to the bottom connector 12, the circuit board unit 11 is electrically connected to the control processing unit. A number of the lower connectors 11d provided changes according to the number of the circuit board units 11.

By having each of the circuit board main bodies 11a inserted into the slots provided in the main body housing 10, the circuit board units 11 are accommodated inside the main body housing 10. As shown by the arrow in FIG. 4, each of the circuit board units 11 is inserted into the main body housing 10 of from a top to a bottom thereof. For example, a plurality of various circuit board units 11 which have different functions exist. In other words, different types of the circuit board unit 11 are accommodated inside the main body housing 10. According to a type thereof, the aforementioned circuit board units 11 are setup in predetermined locations inside the main body housing 10. The tester 2 of the present embodiment includes the incorrect insertion prevention mechanism 20, which prevents the circuit board unit 11 from being inserted into an incorrect location in the main body housing 10 during assembly.

The incorrect insertion prevention mechanism 20 is formed into a shape that corresponds to the type of the circuit board unit 11, and restricts the circuit board unit 11 from being inserted into an incorrect location inside the main body housing 10. As shown in FIG. 4, two incorrect insertion prevention mechanisms 20 are provided for each circuit board unit 11. Out of the two incorrect insertion prevention mechanisms 20, the incorrect insertion prevention mechanism 20 disposed closer to a center location of the circuit board unit 11 in the circuit board extension direction is referred to as a “first incorrect insertion prevention mechanism 30”. The incorrect insertion prevention mechanism 20 disposed closer to an end location of the circuit board unit 11 in the circuit board extension direction, more than the first incorrect insertion prevention mechanism 30, is referred to as a “second incorrect insertion prevention mechanism 40”.

As shown in FIG. 4, one circuit board unit 11 having the first incorrect insertion prevention mechanism 30 and the second incorrect insertion prevention mechanism 40 provided thereon is unevenly distributed to one side (right of FIG. 4) with respect to the center of the lower end edge 11e in an extension direction of the lower end edge 11e of the circuit board unit 11. In other words, the first incorrect insertion prevention mechanism 30 and the second incorrect insertion prevention mechanism 40 are only disposed on one side with respect to the center of the lower end edge 11e, and are not disposed on an opposite side thereof.

Each incorrect insertion prevention mechanism 20 includes a pin unit 21, and a pin receptacle plate 22 (pin receptacle). In the present embodiment, the pin unit 21 is provided in the circuit board unit 11. The pin receptacle plate 22 is provided in the main body housing 10. Conversely, the pin unit 21 may be provided in the main body housing 10, and the pin receptacle plate 22 may be provided in the circuit board unit 11.

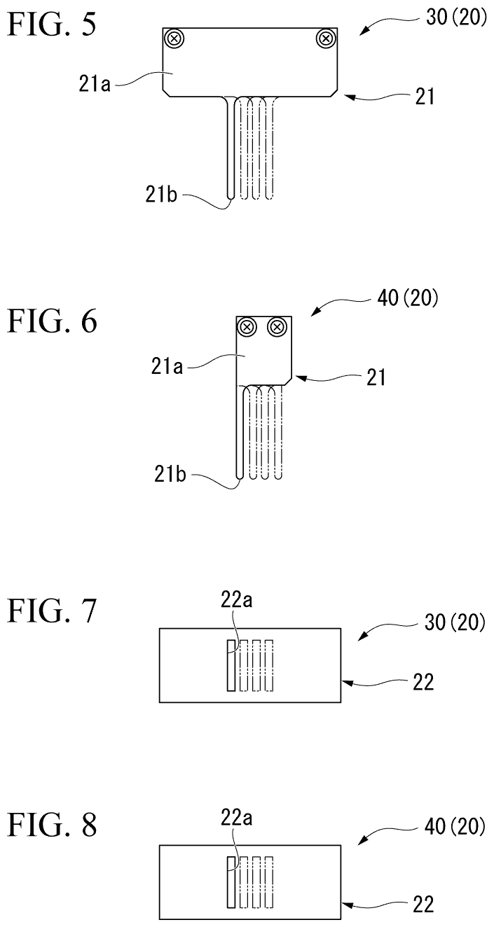

FIG. 5 is an exploded schematic view of the pin 21 unit of the first incorrect insertion prevention mechanism 30. As shown in FIG. 5, the pin unit 21 of the first incorrect insertion prevention mechanism 30 includes a base 21a fixed to the circuit board unit 11, and a pin 21b that protrudes below from the base 21a. There are four locations where it is possible to position the pin 21b in the base 21a. Specifically, the location shown using a solid line on the pin 21b in FIG. 5 and the three locations where the pin 21b is shown using imaginary lines are location where it is possible to dispose the pin 21b on the base 21a. The pin 21b is disposed at a predetermined location according to the type of the circuit board unit 11 in which the first incorrect insertion prevention mechanism 30 is provided.

FIG. 6 is an exploded schematic view of the pin unit 21 of the second incorrect insertion prevention mechanism 40. As in FIG. 6, the second incorrect insertion prevention mechanism 40 also includes the pin unit 21, the base 21a fixed to the circuit board main body 11a, and the pin 21b that protrudes below from the base 21a. The base 21a of the second incorrect insertion prevention mechanism 40 has a smaller length dimension in the extension direction than the length dimension of the base 21a of the first incorrect insertion prevention mechanism 30. Similar to the base 21a of the first incorrect insertion prevention mechanism 30, the base 21a of the second incorrect insertion prevention mechanism 40 has four locations where the pin 21b is disposable. In other words, the length direction of the base 21a changes according to the space where the base 21a is installed. The pin 21b of the second incorrect insertion prevention mechanism 40 also has predetermined locations according to the type of the circuit board unit 11 that the second incorrect insertion prevention mechanism 40 is provided on.

As mentioned above, in the present embodiment, there are four locations where it is possible to dispose the pin 21b in the first incorrect insertion prevention mechanism 30, and four locations where it is possible to dispose the pin 21b in the second incorrect insertion prevention mechanism 40. Accordingly, 16 patterns shapes exist for the incorrect insertion prevention mechanism 20. In other words, the present embodiment is capable of corresponding to 16 types of circuit board units 11 using two incorrect insertion prevention mechanisms 20.

FIG. 7 is a schematic exploded view showing a pin receptacle plate of the first incorrect insertion prevention mechanism in an embodiment of the present invention. As shown in FIG. 7, the pin receptacle hole 22a into which the pin 21b of the first incorrect insertion prevention mechanism 30 is inserted is provided on the pin receptacle plate 22 of the first incorrect insertion prevention mechanism 30. There are four locations where it is possible to dispose the pin receptacle hole 22a on the pin receptacle plate 22. Specifically, it is possible to dispose the pin receptacle hole 22a on the location of the pin receptacle hole 22a in the shown by the solid line on the pin receptacle plate 22 in FIG. 7, or at any of the three locations of the pin receptacle hole 22a shown using imaginary lines. The pin receptacle hole 22a is disposed at a location where the pin receptacle hole 22a faces the pin 21b, and it is possible to insert the pin 21b through.

FIG. 8 is a schematic exploded view of the pin receptacle plate 22 of the second incorrect insertion prevention mechanism 40. As shown in FIG. 8, the pin receptacle hole 22a into which the pin 21b of the second incorrect insertion prevention mechanism 40 is inserted is provided on the pin receptacle plate 22 of the second incorrect insertion prevention mechanism 40. As with the pin receptacle hole 22a of the first incorrect insertion prevention mechanism 30, there are also four locations where it is possible to dispose the pin receptacle hole 22a of the second incorrect insertion prevention mechanism 40. The pin receptacle hole 22a of the second incorrect insertion prevention mechanism 40 is also disposed at a location where the pin receptacle hole 22a faces the pin 21b, and it is possible to insert the pin 21b through.

FIG. 9 is a schematic plan view of the main body housing 10 when seen from above. As shown in FIG. 9, a slot 13 into which the circuit board unit 11 is inserted is provided inside the main body housing 10. Each of the circuit board units 11 has one slot 13 provided, and the slots 13 are arranged in the circuit board direction.

For each one slot 13, the aforementioned bottom connector 12 and two pin receptacle plates 22 are disposed. One out of the two pin receptacle plates 22 is the pin receptacle plate 22 provided in the first incorrect insertion prevention mechanism 30, while the other is the pin receptacle plate 22 provided in the second incorrect insertion prevention mechanism 40. As shown in FIG. 9, adjacent pin receptacle plates 22 into which adjacent slots 13 are disposed may be integrally formed.

In the tester 2, the incorrect insertion prevention mechanism 20 that corresponds to the correct type of the circuit board unit 11 is disposed in each slot 13. As such, even if the incorrect type of circuit board unit 11 is inserted into the slot 13, it is not possible to insert the pin 21b into the pin receptacle hole 22a, and it is not possible to push the circuit board unit 11 through. Therefore, it is possible for an operator to recognize that the incorrect circuit unit board 11 is being pushed into an incorrect slot 13.

Going back to FIG. 2 and FIG. 3, the performance board unit 2b is detachably attached to the main body 2a, and is fixed to the main body 2a using a locking mechanism that is not shown on the drawings. The performance board unit 2b is connected to the probe card 4 from above, and is electrically connectable to the wafer W via the probe card 4.

The aforementioned performance board unit 2b includes the plurality of the lower connectors for a performance board unit which are not shown on the drawings and that are connected to the upper connectors 11c of the circuit board units 11. As shown in FIG. 2 and FIG. 3, the performance board unit 2b includes a plurality of lower connectors for performance board unit 2b1 which are connected to the probe card 4.

When assembling the aforementioned tester 2, the circuit board units 11 are inserted into each slot 13 of the main body housing 10. At such time, even if the incorrect type of circuit board unit 11 is about to be inserted into an incorrect slot 13, the circuit board unit 11 is prevented by the incorrect insertion prevention mechanism 20 from being pushed through. When all the circuit board units 11 are inserted through the respective slots 13, the performance board unit 2b is fixed to the main body 2a, and assembly of the tester 2 is complete.

The tester 2 of the aforementioned present embodiment includes the main body housing 10, the circuit board unit 11, and the incorrect insertion prevention mechanism 20. Along with being inserted and installed inside the main body housing 10, a plurality of circuit board units 11 are provided. A shape of the incorrect insertion prevention mechanism 20 is formed according to the type of the circuit board unit 11, and the incorrect insertion prevention mechanism 20 restricts the incorrect circuit board unit 11 from being inserted into the incorrect location inside the main body housing 10. The incorrect insertion prevention mechanism 20 includes the pin unit 21 and the pin receptacle plate 22. The location in which the pin unit 21 is disposed in corresponds to the type of the circuit board unit 11. The pin receptacle plate 22 has the pin receptacle hole 22a provided in location where the pin 21b of the pin unit 21 is insertable. The tester 2 of the present embodiment has the pin unit 21 installed on the circuit board unit 11, and the pin receptacle plate 22 installed on the main body housing 10.

According to the aforementioned tester 2 of the present embodiment, insertion of the incorrect type of the circuit board unit 11 is restricted using the incorrect insertion prevention mechanism 20. Therefore, according to the tester 2, it is possible to prevent incorrect insertion of the circuit board unit 11 during installation, in the tester 2 which includes a plurality of types of the circuit board units 11 that are accommodated inside the main body housing 10.

In the tester 2 of the present embodiment, a plurality of incorrect insertion prevention mechanisms 20 are provided for a single circuit board unit 11. As such, according to the tester 2 of the present embodiment, by combining the plurality of incorrect insertion prevention mechanisms 20, corresponding to many types of the circuit board unit 11 is possible.

The circuit board unit 11 in the tester 2 of the present embodiment includes the circuit board main body 11a which is inserted into the main body housing 10 in such a way as to have the front and rear surfaces thereof oriented to face the first direction along the horizontal direction. The incorrect insertion prevention mechanism 20 includes the lower end edge 11e of the circuit board unit 11.

According to the aforementioned tester 2 of the present embodiment, since the incorrect insertion prevention mechanism 20 is provided on the lower end edge 11e of the circuit board unit 11, it is possible to assuredly insert the pin 21b into the pin receptacle hole 22a using the weight of the ping 21b. Therefore, it is possible to easily and assuredly insert the circuit board unit 11 into the main body housing 10.

In the tester 2 of the present embodiment, the incorrect insertion prevention mechanism 20 is disposed so as to bias more to one direction from the center of the lower end edge 11e. According to the tester 2 of the present embodiment, it is possible to identify the front and rear of the circuit unit board 11 using the incorrect insertion prevention mechanism 20. For example, in case the circuit board unit 11 is to be inserted in a state where the front and rear surfaces (in other words, the front and rear surfaces of the circuit board main body 11a) thereof face wrong directions, the location of the incorrect insertion prevention mechanism 20 is on an opposite side to the original side. Therefore, according to the tester 2 of the present embodiment, it is possible to prevent errors in the front-rear surface of the circuit board unit 11 from occurring.

The inspection system 1 of the present embodiment includes the tester 2 and the prober 3. The prober 3 moves the wafer W having a semiconductor integrated circuit provided thereon, and is connected to the tester 2. According to an inspection system 1 of the present embodiment, since the inspection system 1 includes the tester 2, it is possible to prevent incorrect insertion into the main body housing 10 of the circuit board unit 11.

Although a preferable embodiment of the present invention is explained above, the embodiment serves as an example, and the present invention should not be construed as being limited to the embodiment herein. Additions, omissions, exchanging of components or other changes may be made so long as they are within the technical scope of the present invention. Therefore, the present invention is not limited to the aforementioned embodiment, but rather by the technical scope of the present invention.

For example, in the aforementioned embodiments, an example where an inspection system that includes the prover 3 as the test object transport device is explained. However, the present invention is not limited thereto. For example, it is possible to apply a handler as the test object transport device included in the inspection system of the present invention. When applying the handler as the test object transport device included in the inspection system of the present invention, the tester 2 is moved with respect to the handler, and the tester 2 is connected to the wafer via the probe card.

The test object is not limited to a wafer. For example, the test object may be a packaged device. In such case, the tester 2 is connected to the device via a test socket.

In the aforementioned present embodiment, a configuration where two incorrect insertion prevention mechanisms 20 are provided for every one circuit board unit 11 is explained. However, the present embodiment is not limited thereto. For example, a configuration where one incorrect insertion prevention mechanism 20 is provided for every one circuit board unit 11, or where three or more incorrect insertion prevention mechanisms 20 are provided for every one circuit board 11 may be adopted.

Although embodiments of the present invention have been described above in detail with reference to the drawings, specific configurations are not limited to the embodiments and other designs and the like may also be included without departing from the objective and scope of the present invention.

What is claims is:

1. A semiconductor testing device comprising:
a housing;
a plurality of circuit board units inserted and installed inside the housing; and
an incorrect insertion prevention mechanism having a shape that corresponds to each type of circuit board unit out of the circuit board units, and restricts the circuit board units from being inserted into an incorrect location in the housing;
wherein
the incorrect insertion prevention mechanism includes
a pin unit which includes a pin which is disposed in a location that corresponds to the type of the circuit board unit, and
a pin receptacle having a pin receptacle hole provided in a location where the pin of the pin unit is insertable, and
the pin unit is installed on a first side of the housing and the circuit board unit, while the pin receptacle is installed on a second side of the housing and the circuit board unit.

2. The semiconductor testing device according to claim 1, wherein
a plurality of the incorrect insertion prevention mechanisms are provided for one of the circuit board unit.

3. The semiconductor testing device according to claim 1, wherein
the circuit board unit includes a circuit board main body which is inserted into the main body housing in an orientation where a front surface and a rear surface thereof face a first direction along a horizontal direction, and
the incorrect insertion prevention mechanism is provided on a lower end edge of the circuit board unit.

4. The semiconductor testing device according to claim 3, wherein
the incorrect insertion prevention mechanism is disposed so as to bias more to one direction from a center of the lower end edge in an extension direction of the lower end edge.

5. An inspection system comprising:
the semiconductor testing device according to claim 1; and
a test object transport device that transports a test object which has a semiconductor integrated circuit provided thereon, and connects the test object to the semiconductor testing device.
